(19) United States
(12) Patent Application Publication
(10) Pub. No.: US 2006/0158101 A1
(43) Pub. Date: Jul. 20, 2006

(54) Organic light-emitting diode

(75) Inventors: Robert Charles Camilletti, Midland, MI (US); Byung Keun Hwang, Midland, MI (US); Mark Jon Loboda, Bay City, MI (US)

Correspondence Address: DOW CORNING CORPORATION CO1232, 2200 W. SALZBURG ROAD, P.O. BOX 994, MIDLAND, MI, 48686-0994, US

(73) Assignee: DOW CORNING CORPORATION, Midland, MI (US)

(21) Appl. No.: 10/547,456

(22) PCT Filed: Feb. 24, 2004
(86) PCT No.: PCT/US04/05437

§ 371 Date: Aug. 30, 2005

Related U.S. Application Data
(60) Provisional application No. 60/451,921, filed on Mar. 4, 2003.

(51) Int. Cl. H05B 33/22; H05B 33/14

(52) U.S. Cl. 313/504; 428/690; 313/503

(57) ABSTRACT

An organic light-emitting diode comprising a first and second barrier coating, wherein the barrier coating is selected from (i) amorphous silicon carbide, (ii) an amorphous silicon carbide alloy comprising at least one element selected from F, N, B, and P, (iii) hydrogenated silicon oxycarbide, (iv) a coating prepared by (a) curing a hydrogen silsesquioxane resin with an electron beam or (b) reacting a hydrogen silsesquioxane resin using a chemical vapor deposition process; and (v) a mutilayer combination of at least two of (i), (ii), (iii), and (iv).

### FIELD OF THE INVENTION

The present invention relates to an organic light-emitting diode (OLED) and more particularly to an organic light-emitting diode containing a first and a second barrier coating.

### BACKGROUND OF THE INVENTION

Organic light-emitting diodes (OLEDs) are useful in a variety of consumer products, such as watches, telephones, lap-top computers, pagers, cellular phones, digital video cameras, DVD players, and calculators. Displays containing light-emitting diodes have numerous advantages over conventional liquid-crystal displays (LCDs). For example, OLED displays are thinner, consume less power, and are brighter than LCDs. Also, unlike LCDs, OLED displays are self-luminous and do not require backlighting. Furthermore, OLED displays have a wide viewing angle, even in bright light. As a result of these combined features, OLED displays are lighter in weight and take up less space than LCD displays. Such benefits notwithstanding, the useful lifespan of OLEDs may be shortened by exposure to environmental elements such as atmospheric water and oxygen.

One approach to reducing the penetration of water and oxygen into an OLED is to seal or encapsulate the device. For example, U.S. Pat. No. 5,920,080 to Jones discloses an organic light-emitting device comprising a substrate, a first conductor overlying the substrate, a layer of light-emitting organic material overlying the first conductor, a second conductor overlying the layer of light-emitting material, a means for restricting light emission in directions parallel to the substrate, and a barrier layer overlying the second conductor.

U.S. Pat. No. 6,069,443 to Jones et al. discloses an organic light-emitting device comprising a substrate, at least one conductor formed on the substrate; a first insulator layer formed on the at least one conductor and said substrate; wherein said insulator layer includes at least one pixel opening formed therein defining a pixel area; a second insulator layer formed on the first insulator layer; and an OLED layer formed on the at least one conductor in the pixel area; and a sealing structure formed over the OLED layer.

U.S. Pat. No. 6,268,695 B1 to Affinito discloses a flexible environmental barrier for an organic light-emitting device, comprising (a) a foundation having (i) a top of a first polymer layer, a first ceramic layer on the first polymer layer, and a second polymer layer on the first ceramic layer; (b) an organic light-emitting device constructed on the second polymer layer of the top; and (c) a cover of a third polymer layer with a second ceramic layer thereon and a fourth polymer layer on the second ceramic layer, the cover deposited on said organic light-emitting device, the foundation and cover encapsulating the organic light emitting device as the flexible environmental barrier.

U.S. Patent Application Publication No. U.S. 2001/0052752 A1 to Ghosh et al. discloses an organic light-emitting diode display device comprising a substrate, at least one organic light-emitting diode device formed thereon, and an encapsulation assembly formed over the substrate and the at least one organic light-emitting diode device, the encapsulation assembly comprising a first encapsulation oxide layer comprising a dielectric oxide, wherein the dielectric oxide of the encapsulation oxide layer lies over and in direct contact with both the substrate and the at least one organic light-emitting diode device, and a second encapsulation layer, wherein the second encapsulation layer covers the first encapsulation layer.

European Patent Application No. EP 0 977 469 A2 to Sheats et al. discloses a method for preventing water or oxygen from a source thereof reaching a device, the method comprising the steps of depositing a first polymer layer between the device and the source, depositing an inorganic layer on the first polymer layer of the device by ECR-PECVD, and depositing a second polymer layer on the inorganic layer.

Although the aforementioned references disclose OLEDs having a range of performance characteristics, there is a continued need for an OLED having superior resistance to water and oxygen and improved reliability.

### SUMMARY OF THE INVENTION

The present invention relates to an organic light-emitting diode comprising:

(A) a substrate having a first opposing surface and a second opposing surface;

(B) a first barrier coating on the first opposing surface of the substrate, wherein the first barrier coating is selected from:
(i) amorphous silicon carbide,
(ii) an amorphous silicon carbide alloy comprising at least one element selected from F, N, B, and P,
(iii) hydrogenated silicon oxycarbide,
(iv) a coating containing silica prepared by (a) curing a hydrogen silsesquioxane resin composition with an electron beam or (b) reacting a hydrogen silsesquioxane resin using a chemical vapor deposition process, and
(v) a multilayer combination of at least two of (i), (ii), (iii), and (iv);

(C) a first electrode layer on the first barrier coating;

(D) a light-emitting element on the first electrode layer;

(D) a second electrode layer on the light-emitting element; and

(E) a second barrier coating on the second electrode layer, wherein the second barrier coating is selected from:
(i) amorphous silicon carbide,
(ii) an amorphous silicon carbide alloy comprising at least one element selected from F, N, B, and P,
(iii) hydrogenated silicon oxycarbide,
(iv) a coating containing silica prepared by (a) curing a hydrogen silsesquioxane resin with an electron beam or (2) reacting a hydrogen silsesquioxane resin using a chemical vapor deposition process, and
(v) a multilayer combination of at least two of (i), (ii), (iii), and (iv); wherein at least one of the first electrode layer and the second electrode layer is transparent, provided when the second electrode layer is nontransparent, the substrate is transparent.

The present invention also relates to an organic light-emitting diode comprising:

(A) a substrate having a first opposing surface and a second opposing surface;

(B) a first electrode layer on the first opposing surface of the substrate;

(C) a light-emitting element on the first electrode layer;

(D) a second electrode layer on the light-emitting element;

(E) a first barrier coating on the second electrode layer, wherein the first barrier coating is selected from:
(i) amorphous silicon carbide,
(ii) an amorphous silicon carbide alloy comprising at least one element selected from F, N, B, and P,
(iii) hydrogenated silicon oxycarbide,
(iv) a coating containing silica prepared by (a) curing a hydrogen silsesquioxane resin with an electron beam or (b) reacting a hydrogen silsesquioxane resin using a chemical vapor deposition process, and
(v) a multilayer combination of at least two of (i), (ii), (iii), and (iv); and

(F) a second barrier coating on the second opposing surface of the substrate, wherein the second barrier coating is selected from:
(i) amorphous silicon carbide,
(ii) an amorphous silicon carbide alloy comprising at least one element selected from F, N, B, and P,
(iii) hydrogenated silicon oxycarbide,
(iv) a coating containing silica prepared by (a) curing a hydrogen silsesquioxane resin with an electron beam or (b) reacting a hydrogen silsesquioxane resin using a chemical vapor deposition process, and
(v) a multilayer combination of at least two of (i), (ii), (iii), and (iv); wherein at least one of the first electrode layer and the second electrode layer is transparent, provided when the second electrode layer is nontransparent, the substrate is transparent.

The OLED of the present invention exhibits good resistance to abrasion, organic solvents, moisture, and oxygen. In particular, the OLED has very low permeability to water vapor and oxygen.

Displays containing the organic light-emitting diode of the present invention have numerous advantages including thin form, low power consumption, wide viewing angle, lightweight, and minimal size. Additionally, the displays can be fabricated on a wide variety of flexible substrates, ranging from optically clear plastic films to reflective metal foils. Compared to traditional OLED displays fabricated on glass substrates, such OLED displays are flexible and can conform to a variety of shapes. The thin plastic substrates also reduce the weight of displays, an important consideration in devices such as portable computers and large-area television screens. Flexible OLED displays are also less susceptible to breakage and more impact resistant than their glass counterparts. Finally, flexible OLED displays potentially cost less to manufacture than their glass counterparts due to the production advantages of roll-to-roll processing.

The organic light-emitting diode of the present invention is useful as a discrete light-emitting device or as the active element of light-emitting arrays or displays, such as flat panel displays. OLED displays are useful in a number of devices, including watches, telephones, lap-top computers, pagers, cellular phones, digital video cameras, DVD players, and calculators.

These and other features, aspects, and advantages of the present invention will become better understood with reference to the following description, appended claims, and accompanying drawings.

### BRIEF DESCRIPTION OF THE DRAWINGS

FIG. 1 shows a cross-sectional view of a first embodiment of an OLED according to the present invention.

FIG. 2 shows a cross-sectional view of a second embodiment of an OLED according to the present invention.

FIG. 3 shows a cross-sectional view of a third embodiment of an OLED according to the present invention.

### DETAILED DESCRIPTION OF THE INVENTION

As used herein, the term “transparent” means the particular component (e.g., substrate or electrode layer) has a percent transmittance of at least 30%, alternatively at least 60%, alternatively at least 80%, for light in the visible region (˜400 to ˜700 nm) of the electromagnetic spectrum. Also, as used herein, the term “nontransparent” means the component has a percent transmittance less than 30% for light in the visible region of the electromagnetic spectrum.

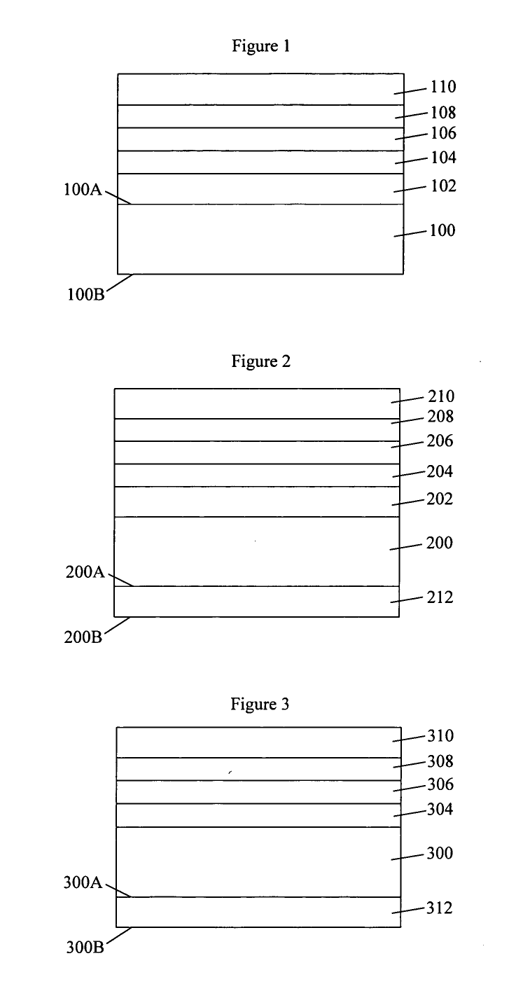

As shown in FIG. 1, a first embodiment of an OLED according to the present invention comprises a substrate 100 having a first opposing surface 100A and a second opposing surface 100B, a first barrier coating 102 on the first opposing surface 100A of the substrate 100, a first electrode layer 104 on the first barrier coating 102, a light-emitting element 106 on the first electrode layer 104, a second electrode layer 108 on the light-emitting element 106, and a second barrier coating 110 on the second electrode layer 108.

The substrate can be a rigid or flexible material having two opposing surfaces. Further, the substrate can be transparent or nontransparent to light in the visible region of the electromagnetic spectrum, provided when the second electrode layer is nontransparent, the substrate is transparent. Examples of substrates include, but are not limited to, semiconductor materials such as silicon, silicon having a surface layer of silicon dioxide, and gallium arsenide; quartz; fused quartz; aluminum oxide; ceramics; glass; metal foils; polyolefins such as polyethylene, polypropylene, polystyrene, and polyethyleneterephthalate; fluorocarbon polymers such as polytetrafluoroethylene and polyvinylfluoride; polyamides such as Nylon; polyimides; polyesters such as poly(methyl methacrylate); epoxy resins; polyethers; polycarbonates; polysulfones; and polyether sulfones.

The first barrier coating is selected from (i) amorphous silicon carbide, (ii) an amorphous silicon carbide alloy comprising at least one element selected from F, N, B, and P, (iii) hydrogenated silicon oxycarbide, (iv) a coating containing silica prepared by (a) curing a hydrogen silsesquioxane resin with an electron beam or (b) reacting a hydrogen silsesquioxane resin using a chemical vapor deposition process, and (v) a multilayer combination of at least two of (i), (ii), (iii), and (iv). The first barrier coating typically has a thickness of from 0.1 to 10 μm, alternatively from 0.1 to 6 μm, alternatively from 0.2 to 4 μm. When the thickness of the first barrier coating is less than 0.1 μm, the permeability of the barrier to water and oxygen is moderate to high.

Barrier coatings (i), (ii), (iii)(b), and (iv) can be deposited by a variety of chemical vapor deposition (CVD) techniques including plasma-enhanced chemical vapor deposition (PECVD), photochemical vapor deposition, jet vapor deposition; and a variety of physical vapor deposition methods including sputtering and electron beam evaporation. The coating is typically deposited at a temperature not greater than about 100° C., to avoid damage to the substrate and/or light-emitting element of the OLED. The method selected for a particular application depends on several factors including the thermal stability of the OLED components and the susceptibility of the components to chemical attack by reacting gases or byproducts.

In PECVD, coatings are deposited by means of a chemical reaction between gaseous reactants in a plasma field passing over a substrate. Generally, PECVD processes occur at lower substrate temperatures than conventional CVD. For instance, substrate temperatures from about room temperature to about 100° C. can be used in a PECVD process.

The plasma used in PECVD processes can comprise energy derived from a variety of sources such as electric discharges, electromagnetic fields in the radio-frequency or microwave range, lasers, and particle beams. Radio frequency (10 kHz to 102 MHz) or microwave (0.1 to 10 GHz) energy at moderate power densities (0.1 to 5 watts/cm²) is typically used in PECVD processes. The specific frequency, power and pressure, however, typically depend on the precursor gases and configuration of the deposition system.

The amorphous silicon carbide of the present invention, also referred to as “hydrogenated silicon carbide” in the art, contains hydrogen in addition to silicon and carbon. For example, the amorphous silicon carbide may be represented by the general formula SiₐC_{b}H_{c}, where b has a value greater than a, c has a value of from 5 to 45 atomic %, and a+b+c is 100 atomic %.

The amorphous silicon carbide of the present typically contains an excess of carbon relative to silicon. For example, the atomic ratio of carbon to silicon is typically from 1.1 to 10:1, alternatively from 1.1 to 5:1, alternatively from 1.1 to 2:1. When the ratio of carbon to silicon is less than 1.1:1, the coating has very low transparency. When the ratio is greater than 5:1, the coating has high stress and is susceptible to peeling.

Methods of preparing amorphous silicon carbide by chemical or physical vapor deposition of suitable precursor gases are well known in the art, as exemplified in U.S. Pat. No. 5,818,071 to Loboda et al.; U.S. Pat. No. 5,011,706 to Tarhay et al.; U.S. Pat. No. 6,268,262 B1 to Loboda; U.S. Pat. No. 5,693,565 to Camilletti et al.; U.S. Pat. No. 5,753,374 to Camilletti et al.; and U.S. Pat. No. 5,780,163 to Camilletti et al. Examples of suitable precursor gases include (1) mixtures of silane or a halosilane such as trichlorosilane, and an alkane having one to six carbon atoms such as methane, ethane, propane, etc.; (2) an alkylsilane such as methylsilane, dimethylsilane and trimethylsilane; or (3) a silacyclobutane or disilacyclobutane.

The amorphous silicon carbide alloy of the present invention comprises at least one element selected from F, N, B, and P. For example, the amorphous silicon carbide alloy may be represented by the general formula Si_{d}CₑH_{f}X_{g}, wherein X is selected from at least one of F, N, B, and P; the atomic ratio of C to Si is from 1.1:1 to 10:1, alternatively from 1.1 to 5:1, alternatively from 1.1 to 2:1; f has a value of from 5 to 45 atomic %; g has a value of from 1 to 20 atomic %, alternatively from 1 to 10 atomic %, alternatively from 5 to 10 atomic %; and the sum d+e+f+g=100 atomic %.

Methods of preparing amorphous silicon carbide alloys are well known in the art. For example, European Patent Application No. EP 0 771 886 A1 to Loboda discloses a method of depositing an amorphous coating containing silicon, carbon, nitrogen, and hydrogen on a substrate comprising introducing a reactive gas mixture comprising an organosilicon compound and a source of nitrogen into a deposition chamber containing the substrate; and inducing reaction of the reactive gas mixture to form the amorphous coating. Examples of organosilicon compounds include alkylsilanes such as methylsilane, dimethylsilane, and trimethylsilane; disilanes such as hexamethyldisilane; trisilanes such as octamethyltrisilane; low molecular weight polysilanes such as dimethyl polysilane; low molecular weight polycarbosilanes and silicon-containing cycloalkanes such as silacyclobutanes and disilacyclobutanes. Examples of sources of nitrogen include nitrogen; primary amines such as methylamine; secondary amines such as dimethylamine; tertiary amines such as trimethylamine; and ammonia.

Amorphous silicon carbide alloys containing fluorine, boron, or phosphorous can be produced by introducing a fluorine-containing gas, a boron-containing gas, or a phosphorous-containing gas, respectively, into the reactive gas mixture typically used to deposit amorphous silicon carbide. Examples of fluorine-containing gases include F₂, SiF₄, CF₄, C₃F₆, and C₄F₈. Examples of boron-containing gases include diborane and (CH₃)₃B. Examples of phosphorus-containing gases include phosphine and trimethylphosphine.

The hydrogenated silicon oxycarbide of the present invention contains silicon, oxygen, carbon, and hydrogen. For example, the hydrogenated silicon oxycarbide may be represented by the general formula SiₘOₙCₚH_{q} wherein m has value of from 10 to 33 atomic %, alternatively 18 to 20 atomic %; n has a value of from 1 to 66 atomic %, alternatively from 18 to 21 atomic %; p has a value of from 1 to 66 atomic %, alternatively from 5 to 38 atomic %; q has a value of from 0.1 to 60 atomic %, alternatively from 25 to 32 atomic %; and m+n+p+q=100 atomic %.

Methods of preparing hydrogenated silicon oxycarbide are well known in the art, as exemplified in U.S. Pat. No. 6,159,871 to Loboda et al.; WO 02/054484 A2 to Loboda; U.S. Pat. No. 5,718,967 to Hu et al.; and U.S. Pat. No. 5,378,510 to Thomas et al. For example, U.S. Pat. No. 6,159,871 discloses a chemical vapor deposition method for producing hydrogenated silicon oxycarbide films comprising introducing a reactive gas mixture comprising a methyl-containing silane and an oxygen-providing gas into a deposition chamber containing a substrate and inducing a reaction between the methyl-containing silane and the oxygen-providing gas at a temperature of 25 to 500° C.; wherein there is a controlled amount of oxygen present during the reaction to provide a film comprising hydrogen, silicon, carbon, and oxygen having a dielectric constant of 3.6 or less on the substrate. Examples of methyl-containing silanes include methyl silane, dimethylsilane, trimethylsilane, and tetramethylsilane. Examples of oxygen-providing gases include, but are not limited to, air, ozone, oxygen, nitrous oxide, and nitric oxide.

The amount of oxygen present during the deposition process can be controlled by selection of the type and/or amount of the oxygen-providing gas. The concentration of oxygen-providing gas is typically less than 5 parts per volume, alternatively from 0.1 to 4.5 parts per volume, per 1 part per volume of the methyl-containing silane. When the concentration of oxygen is too high, the process forms a silicon oxide film with a stoichiometry close to SiO₂. When the concentration of oxygen is too low, the process forms a silicon carbide film with a stoichiometry close to SiC. The optimum concentration of the oxygen-containing gas for a particular application can be readily determined by routine experimentation.

The reactive gas mixture may contain additional gaseous species, including carrier gases such as helium or argon; dopants such as phosphine and diborane; halogens such as fluorine, halogen-containing gases such as SiF₄, CF₄, C₃F₆, and C₄F₈; and any other material that provides desirable properties to the coating.

The coating containing silica can be prepared by curing a hydrogen silsesquioxane resin with an electron beam. The hydrogen silsesquioxane resin (H-resin) of the present invention may be represented by the general formula HSi(OH)ₓ(OR)_{y}O_{Z/2}, wherein each R is independently a hydrocarbyl group which, when bonded to silicon through the oxygen atom, forms a hydrolyzable substituent, x=0 to 2, y=0 to 2, z=1 to 3, and x+y+z=3. Examples of hydrocarbyl groups include alkyl such as methyl, ethyl, propyl, and butyl; aryl such as phenyl; and alkenyl such as allyl and vinyl. These resins may be fully condensed (HSiO_{3/2})ₙ or partially hydrolyzed (i.e., containing some Si—OR groups) and/or partially condensed (i.e., containing some Si—OH groups). Although not represented by the formula above, the resin may contain a small number (e.g., less than about 10%) of silicon atoms to which are bonded either 0 or 2 hydrogen atoms.

Methods of preparing H-resins are well known in the art as exemplified in U.S. Pat. No. 3,615,272 to Collins et al.; U.S. Pat. No. 5,010,159 to Bank et al.; U.S. Pat. No. 4,999,397 to Frye et al.; U.S. Pat. No. 5,063,267 to Hanneman et al.; U.S. Pat. No. 4,999,397 to Frye et al.; Kokai Patent No. 59-178749; Kokai Patent No. 60-86017; and Kokai Patent No. 63-107122.

The H-resin can be diluted in a solvent, such as an organic solvent or silicone fluid, to facilitate application of the composition to a surface. Examples of organic solvents include aromatic hydrocarbons such as benzene and toluene; alkanes such as n-heptane and dodecane; ketones; esters; and ethers. Examples of silicone fluids include linear, branched and cyclic polydimethylsiloxanes. The concentration of the solvent is typically from about 0.1 to 50 weight percent, based on the total weight of the composition.

The H-resin can be applied to the surface of the substrate using a conventional method such as spin-coating, dip-coating, spray-coating or flow-coating. When the H-resin is applied in a solvent, the method can further comprise removing at least a portion of the solvent from the film. For example, the solvent can be removed by air-drying under ambient conditions, application of a vacuum, or mild heating (eg., less than 50° C.). When spin-coating is used, the drying period is minimized, as spinning facilitates removal of the solvent.

Once the H-resin is applied to the substrate, it can be cured by exposing it to an electron beam, as described in U.S. Pat. No. 5,609,925 to Camilletti et al. Typically, the accelerating voltage is from about 0.1 to 100 keV, the vacuum is from about 10 to 10-3 Pa, the electron current is from about 0.0001 to 1 ampere, and the power varies from about 0.1 watt to 1 kilowatt. The dose is typically from about 100 microcoulomb to 100 coulomb/cm², alternatively from about 1 to 10 coulombs/cm². The H-resin is generally exposed to the electron beam for a time sufficient to provide the dose required to convert the H-resin to a coating containing silica. Depending on the voltage, the time of exposure is typically from about 10 seconds to 1 hour.

The coating containing silica can also be prepared by reacting a hydrogen silsesquioxane resin using a chemical vapor deposition process. Methods of producing coatings containing silicon and oxygen from vaporized H-resins are known in the art, as exemplified in U.S. Pat. No. 5,165,955 to Gentle. An H-resin, as described above, is fractionated to obtain low molecular weight species that can be volatilized in a CVD process. Although H-resins having a broad molecular weight may be used in the deposition process, volatilization of such materials often leaves a residue comprising nonvolatile species. Suitable fractions of H-resins include those that can be volatilized under moderate temperature and/or vacuum conditions. Generally, such fractions are those in which at least about 75% of the species have a number-average molecular weight less than about 2000, alternatively less than about 1200, alternatively from about 400 to 1000.

Methods of fractionating polymers, such as solution fractionation, sublimation, and supercritical fluid extraction are known in the art. For example, U.S. Pat. No. 5,063,267 to Hanneman et al. discloses a process comprising (1) contacting an H-resin with a fluid at, near, or above its critical point for a time sufficient to dissolve a fraction of the polymer; (2) separating the fluid containing the fraction from the residual polymer; and (3) recovering the desired fraction. Specifically, the process involves charging an extraction vessel with a sample of H-resin and then passing an extraction fluid through the vessel. The extraction fluid and its solubility characteristics are controlled so that only the desired molecular weight fractions of H-resin are dissolved in the fluid. The solution containing the desired fractions of H-resin is then removed from the vessel, separating it from H-resin fractions not soluble in the fluid and any other insoluble materials such as gels or contaminants. The desired H-resin fraction is then recovered from the solution by altering the solubility characteristics of the solvent and precipitating the desired fraction.

The extraction fluid can be any compound that dissolves the desired fraction of H-resin and does not dissolve the remaining fractions at, near, or above the critical point of the fluid. Examples of extraction fluids include, but are not limited to, carbon dioxide and low molecular weight hydrocarbons such as ethane and propane.

The desired fraction of H-resin is vaporized and introduced into a deposition chamber containing the substrate to be coated. Vaporization may be accomplished by heating the H-resin sample above its vaporization point, by application of vacuum, or a combination thereof. Generally, vaporization may be accomplished at temperatures from 50 to 300° C. under atmospheric pressure or at lower temperature (near room temperature) under vacuum.

The concentration of H-resin vapor is sufficient to deposit the desired coating. The concentration can vary over a wide range depending on factors such as the desired coating thickness, the area to be coated, etc. In addition, the vapor may be combined with a carrier gas such as air, argon or helium.

The vaporized H-resin is then reacted to deposit the coating on the substrate. The reaction can be carried out using a variety of chemical vapor deposition (CVD) techniques including plasma-enhanced chemical vapor deposition (PECVD), photochemical vapor deposition, and jet vapor deposition.

The first barrier coating can also be a multilayer combination of at least two of (i), (ii), (iii), and (iv) above. Examples of multilayer combinations include, but are not limited to, SiC:H/SiCO:H/SiC:H; SiC:H/SiCO:H; SiCO:H/SiC:H; and SiCN:H/SiC:H.

The first electrode layer can function as an anode or cathode in the OLED. The first electrode layer may be transparent or nontransparent to visible light. The anode is typically selected from a high work-function (>4 eV) metal, alloy, or metal oxide such as indium oxide, tin oxide, zinc oxide, indium tin oxide (ITO), indium zinc oxide, aluminum-doped zinc oxide, nickel, and gold. The cathode can be a low work-function (<4 eV) metal such as Ca, Mg, and Al; a high work-function (>4 eV) metal, alloy, or metal oxide, as described above; or an alloy of a low-work function metal and at least one other metal having a high or low work-function, such as Mg—Al, Ag—Mg, Al—Li, In—Mg, and Al—Ca. Methods of depositing anode and cathode layers in the fabrication of OLEDs, such as evaporation, co-evaporation, DC magnetron sputtering, or RF sputtering, are well known in the art.

The light-emitting element comprises an emissive layer and one or more additional organic layers. When an appropriate voltage is applied to the OLED, the injected positive and negative charges recombine in the emissive layer to produce light (electroluminscense). The organic layers are chosen to maximize the recombination process in the emissive layer, thus maximizing light output from the OLED device. Organic layers other than the emissive layer are typically selected from a hole-injection layer, a hole-transport layer, an electron-injection layer, and an electron transport layer. However, a single hole-injection and hole transport layer, and a single electron-injection and electron-transport layer may be used in the OLED. The emissive layer can also function as an electron-injection and electron-transport layer. The thickness of the light-emitting element is typically from 5 to 100 nm, alternatively from 25 to 75 nm.

The organic materials used in the light-emitting element include small molecules or monomers, and polymers. Monomers can be deposited by standard thin film techniques such as vacuum evaporation or sublimation. Polymers can be deposited by conventional solvent coating techniques such as spin-coating, dipping, spraying, brushing, and screen printing. Materials used in the construction of light-emitting elements and methods of preparing such elements are well known in the art, as exemplified in U.S. Pat. Nos. 4,356,429; 4,720,432; 5,593,788; 5,247,190; 4,769,292; 4,539,507; 5,920,080; 6,255,774; 6,048,573; 5,952,778; 5,969,474; 6,262,441 B1; 6,274,979 B1; 6,307,528 B1; and 5,739,545.

The orientation of the light-emitting element depends on the arrangement of the anode and cathode in the OLED. The hole injection and hole transport layer(s) are located between the anode and emissive layer and the electron-injection and electron-transport layer(s) are located between the emissive layer and the cathode.

The second electrode layer can function either as an anode or cathode in the OLED. The second electrode layer may be transparent or nontransparent to light in the visible region, provided when then second electrode layer is nontransparent, the substrate is transparent. Examples of anode and cathode materials and methods for their formation are as described above for the first electrode layer.

The second barrier coating is selected from (i) amorphous silicon carbide, (ii) an amorphous silicon carbide alloy comprising at least one element selected from F, N, B, and P, (iii) hydrogenated silicon oxycarbide, (iv) a coating prepared by (a) curing a hydrogen silsesquioxane resin with an electron beam or (b) reacting a hydrogen silsesquioxane resin using a chemical vapor deposition process, and (v) a multilayer combination of at least two of (i), (ii), (iii), and (iv); wherein (i) through (v) are as described and exemplified above for the first barrier coating.

As shown in FIG. 2, a second embodiment of an OLED according to the present invention comprises a substrate 200 having a first opposing surface 200A and a second opposing surface 200B, a first barrier coating 202 on the first opposing surface 200A of the substrate 200, a first electrode layer 204 on the first barrier coating 202, a light-emitting element 206 on the first electrode layer 204, a second electrode layer 208 on the light-emitting element 206, a second barrier coating 210 on the second electrode layer 208, and a third barrier coating 212 on the second opposing surface 200B of the substrate 200. The third barrier coating 212 is as defined and exemplified above for the first and second barrier coatings.

As shown in FIG. 3, a third embodiment of an OLED according to the present invention comprises a substrate 300 having a first opposing surface 300A and a second opposing surface 300B, a first electrode layer 304 on the first opposing surface 300A of the substrate 300, a light-emitting element 306 on the first electrode layer 304, a second electrode layer 308 on the light-emitting element 306, a first barrier coating 310 on the second electrode layer 308, and a second barrier coating 312 on the second opposing surface 300B of the substrate 300.

The OLED of the present invention exhibits good resistance to abrasion, organic solvents, moisture, and oxygen. In particular, the OLED has very low permeability to water vapor and oxygen.

The organic light-emitting diode of the present invention is useful as a discrete light-emitting device or as the active element of light-emitting arrays or displays, such as flat panel displays. OLED displays are useful in a number of devices, including watches, telephones, lap-top computers, pagers, cellular phones, digital video cameras, DVD players, and calculators.

### EXAMPLES

The following examples are presented to better illustrate the barrier coating of the present invention, but are not to be considered as limiting the invention, which is delineated in the appended claims.

Water vapor transmission rate (WVTR) of a coating was determined according to ASTM Standard E96 using a MOCON PERMATRAN Permeation Test System at a relative humidity of 100%.

### Examples 1-7

In each Example, a barrier coating was deposited on a polyethylene terephthalate (PET) substrate having a diameter of 15.2 cm and thickness of 75 μm by introducing the gas mixture specified in Table 1 into a capacitively coupled parallel plate PECVD system operating in a reactive ion-etching (RIE) mode (RF coupled to bottom electrode) with a substrate temperature of 45 to 75° C., a pressure of 0.17 to 0.47 Torr, and a DC bias of 150 to 300 V. The process parameters and properties for each coating are shown in Table 1.

TABLE 1

| | Process Parameters | | | | | Film Properties | | | | | | |
|---|---|---|---|---|---|---|---|---|---|---|---|---|
| Film | Gas Flow Rate, sccm | | | | RF Power | Dep. Rate | | A 630 | | WVTR (g/m²/day) | | Thickness |
| Type | Me₃SiH | He (Ar) | Other | | (W) | (Å/min.) | RI | (μm⁻¹) | T 630 | Coated | Uncoated | (μm) |
| SiC:H | 300 | 1250 | — | | 450 | 1409 | 2.0416 | 0.090056 | 0.7295 | 3.72 | 12.44 | 3.0 |
| SiC:H | 150 | 1500 | — | | 500 | 1404 | 2.1773 | — | 0.6923 | 0.1982 | 12.1-13.5 | 1.5 |
| SiC:H | 60 | 600 (Ar) | — | | 500 | 1224 | 2.28 | 0.6 | 0.585 | 0.1819 | 12.1-13.5 | 1.5 |
| SiCF:H | 60 | 600 (Ar) | 40 | (CF₄) | 500 | 1455 | 2.0592 | 0.02264 | 0.7272 | 0.0998 | 12.1-13.5 | 1.5 |
| SiCN:H | 150 | 1500 | N₂ | (purge) | 500 | 1554 | 2.0816 | 0.1726 | 0.7346 | 0.1705 | 12.1-13.5 | 1.5 |
| SiCO:H | 150 | 1500 | 50 | (N₂O) | 500 | 1675 | 1.9613 | 0.07554 | 0.7877 | 0.5767 | 12.1-13.5 | 1.5-1.6 |
| SiCO:H | 150 | 1500 | 7 | (O₂) | 500 | 2061 | 1.7851 | 0.02485 | 0.8439 | 0.68-0.90 | 12.1-13.5 | 2.0 |

Dep. Rate is deposition rate, RI is refractive index, A 630 is absorption coefficient at 630 nm, T 630 is transmittance at 630 nm, WVTR is water vapor transmission rate, coated refers to a coated PET substrate, uncoated refers to an uncoated PET substrate, and the entry “—” indicates the measurement was not performed.

That which is claimed is:

1. An organic light-emitting diode comprising:
(A) a substrate having a first opposing surface and a second opposing surface;
(B) a first barrier coating on the first opposing surface of the substrate, wherein the first barrier coating is selected from:
(i) amorphous silicon carbide,
(ii) an amorphous silicon carbide alloy comprising at least one element selected from F, N, B, and P,
(iii) hydrogenated silicon oxycarbide,
(iv) a coating containing silica prepared by (a) curing a hydrogen silsesquioxane resin with an electron beam or (b) reacting a hydrogen silsesquioxane resin using a chemical vapor deposition process, and
(v) a multilayer combination of at least two of (i), (ii), (iii), and (iv);
(C) a first electrode layer on the first barrier coating;
(D) a light-emitting element on the first electrode layer;
(D) a second electrode layer on the light-emitting element; and
(E) a second barrier coating on the second electrode layer, wherein the second barrier coating is selected from:
(i) amorphous silicon carbide,
(ii) an amorphous silicon carbide alloy comprising at least one element selected from F, N, B, and P,
(iii) hydrogenated silicon oxycarbide,
(iv) a coating containing silica prepared by (a) curing a hydrogen silsesquioxane resin with an electron beam or (2) reacting a hydrogen silsesquioxane resin using a chemical vapor deposition process, and
(v) a multilayer combination of at least two of (i), (ii), (iii), and (iv); wherein at least one of the first electrode layer and the second electrode layer is transparent, provided when the second electrode layer is nontransparent, the substrate is transparent.

2. The organic light-emitting diode according to claim 1, wherein the first barrier coating and the second barrier coating are each amorphous silicon carbide.

3. The organic light-emitting diode according to claim 2, wherein the amorphous silicon carbide has the formula Si_{d}CₑH_{f}X_{g}, wherein X is selected from at least one of F, N, B, and P; the atomic ratio of C to Si is from 1.1:1 to 10:1; f has a value of from 5 to 45 atomic %; g has a value of from 1 to 20 atomic %; and the sum d+e+f+g=100 atomic %.

4. The organic light-emitting diode according to claim 1, wherein the first barrier coating and the second barrier coating are each a multilayer combination of at least two of (i), (ii), (iii), and (iv), wherein each multilayer combination contains amorphous silicon carbide.

5. An organic light-emitting diode comprising:
(A) a substrate having a first opposing surface and a second opposing surface;
(B) a first electrode layer on the first opposing surface of the substrate;
(C) a light-emitting element on the first electrode layer;
(D) a second electrode layer on the light-emitting element;
(E) a first barrier coating on the second electrode layer, wherein the first barrier coating is selected from:
(i) amorphous silicon carbide,
(ii) an amorphous silicon carbide alloy comprising at least one element selected from F, N, B, and P,
(iii) hydrogenated silicon oxycarbide,
(iv) a coating containing silica prepared by (a) curing a hydrogen silsesquioxane resin with an electron beam or (b) reacting a hydrogen silsesquioxane resin using a chemical vapor deposition process, and
(v) a multilayer combination of at least two of (i), (ii), (iii), and (iv); and
(F) a second barrier coating on the second opposing surface of the substrate, wherein the second barrier coating is selected from:
(i) amorphous silicon carbide,
(ii) an amorphous silicon carbide alloy comprising at least one element selected from F, N, B, and P,
(iii) hydrogenated silicon oxycarbide,
(iv) a coating containing silica prepared by (a) curing a hydrogen silsesquioxane resin with an electron beam or (b) reacting a hydrogen silsesquioxane resin using a chemical vapor deposition process, and
(v) a multilayer combination of at least two of (i), (ii), (iii), and (iv); wherein at least one of the first electrode layer and the second electrode layer is transparent, provided when the second electrode layer is nontransparent, the substrate is transparent.

6. The organic light-emitting diode according to claim 5, wherein the first barrier coating and the second barrier coating are each amorphous silicon carbide.

7. The organic light-emitting diode according to claim 6, wherein the amorphous silicon carbide has the formula Si_{d}CₑH_{f}X_{g}, wherein X is selected from at least one of F, N, B, and P; the atomic ratio of C to Si is from 1.1:1 to 10:1; f has a value of from 5 to 45 atomic %; g has a value of from 1 to 20 atomic %; and the sum d+e+f+g=100 atomic %.

8. The organic light-emitting diode according to claim 5, wherein the first barrier coating and the second barrier coating are each a multilayer combination of at least two of (i), (ii), (iii), and (iv), wherein each multilayer combination contains amorphous silicon carbide.
